(19) United States
(12) Patent Application Publication
(10) Pub. No.: US 2003/0116803 A1
(43) Pub. Date: Jun. 26, 2003

(54) Cylinder type transistor with vertical silicon-on-insulator structure and fabrication method thereof

(76) Inventor: Cheol Soo Park, Kyoungki-do (KR)

Correspondence Address: WILDMAN, HARROLD, ALLEN & DIXON, 225 WEST WACKER DRIVE, CHICAGO, IL, 60606, US

(21) Appl. No.: 10/325,288

(22) Filed: Dec. 19, 2002

(30) Foreign Application Priority Data
Dec. 20, 2001 (KR) 2001-81788

(51) Int. Cl. H01L 27/01

(52) U.S. Cl. 257/347

(57) ABSTRACT

A cylinder type transistor and a fabrication method thereof. The transistor comprises: a well zone of a first conductive type formed on a silicon substrate; a drain of a second conductive type formed at a predetermined depth of the well zone; a plurality of silicon bulks located in the well zone above the drain; a source of the second conductive type formed on the silicon bulks; a gate filling the inside of the silicon bulks with a gate oxide layer interposed therein; an isolation oxide layer formed on an entire surface of a resultant structure, exposing a portion of the gate, the source and the drain; and contact plugs one electrically connected to the gate, the source and the drain, respectively, as exposed through the isolation oxide layer.

### BACKGROUND OF THE INVENTION

1. Field of the invention

The present invention relates to a method for fabricating a transistor of a semiconductor integrated circuit device, and more particularly to a cylinder type transistor with a vertical silicon-on-insulator structure and a fabrication method thereof.

2. Description of the Prior Art

As generally known in the art, a semiconductor integration circuit device employs MOSFETs (metal oxide semiconductor field effect transistor) as unit transistors and forms an integration circuit through having a number of the unit transistors integrated into the same device. This type of general transistor has a horizontal structure. Thus, as the degree of integration increases, the dependence on lithography will become greater and the available channels will become substantially weakened, thus causing disadvantages.

For instance, as channel length of the transistor decreases, the short channel effect in which a threshold voltage lowers and the reverse short channel effect in which the threshold voltage rises, and a gate induced drain leakage (GIDL) phenomenon occurs in a device employing a thin gate oxide layer. Also, a punch through phenomenon is deepened. Further, when the transistor is not in a state of operation, the increase of current leakage, the increase of junction capacitance in the source and drain region, and the fluctuation of threshold voltage occur.

Meanwhile, various research and development has been and is being carried out in the art in order to achieve high current drivability, extremely high speed and extremely low power consumption.

### SUMMARY OF THE INVENTION

Accordingly, the present invention has been made to solve the above-mentioned problems occurring in the prior art, and an object of the present invention is to provide a new cylinder type transistor with a vertical silicon-on-insulator structure and a fabrication method thereof, which make it possible for devices to obtain higher integration and improved electrical characteristics and reliability.

In order to accomplish these objects, according to the present invention, there is provided a cylinder type transistor with a silicon-on-insulator structure, the transistor comprising: a well zone of a first conductive type formed on a silicon substrate; a drain of a second conductive type formed at a predetermined depth of the well zone; a plurality of silicon bulks in the form of vertical cylinders located in the well zone above the drain; a source of the second conductive type formed on the silicon bulks away from the drain in the vertical direction; a gate filling the inside of the silicon bulks with a gate oxide layer interposed in the silicon bulks; an isolation oxide layer formed on an entire surface of a resultant structure, exposing a portion of the gate, the source and the drain; and contact plugs one electrically connected to the gate, the source and the drain, respectively, as exposed through the isolation oxide layer; wherein transistor channels is formed in the silicon bulks and the isolation oxide layer fills spaces formed between the outer walls of the silicon bulks.

According to another aspect of the present invention, the cylinder type transistor further comprises a masking oxide layer and a masking nitride layer formed on the silicon bulks.

According to another aspect of the present invention, the thickness of the gate oxide layer formed on the surface of the source and the drain is greater than that formed on the surface of the well zone.

According to another aspect of the present invention, there is provided a method for fabricating a cylinder type transistor, the method comprising steps of forming a well zone of a first conductive type on a silicon substrate; forming a drain of a second conductive type at a predetermined depth of the well zone and forming a source above the well zone away from the drain in a vertical direction; forming a cylindrical trench by etching the source and the well zone in sequence, exposing the drain by use of a transistor mask with a circular exposure area; forming a gate oxide layer on an inner surface of the trench and forming a gate inside the trench; forming a cylindrical silicon bulk, the inside of which is filled with the gate oxide layer and the gate and the outer wall of which is exposed, by etching the source and the well zone in sequence using an isolation mask to expose the drain, the diameter of the circular shield area of the isolation mask being greater than that of the circular exposure area of the transistor mask; depositing an isolation oxide layer on an entire surface of a resultant structure to expose a portion of the gate, the source and the drain; forming contact plugs electrically connected to the drain, the source and the drain, respectively, as exposed through the isolation oxide layer.

According to another aspect of the present invention, the method for fabricating a cylindrical transistor also comprises steps of forming a masking oxide layer and a masking nitride layer in sequence, after the step of forming the drain and the source.

According to another aspect of the present invention, the step of forming the gate oxide layer is achieved by a thermal oxidization.

### BRIEF DESCRIPTION OF THE DRAWINGS

The above and other objects, features and advantages of the present invention will be more apparent from the following detailed description taken in conjunction with the accompanying drawings, in which:

FIG. 1 shows an arrangement of masks used for fabricating a cylinder type transistor with a vertical silicon-on-insulator structure according to an embodiment of the present invention.

FIGS. 2 to 7 are explanatory views in cross-section illustrating a cylinder type transistor with a vertical silicon-on-insulator structure and a fabrication method thereof according to an embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

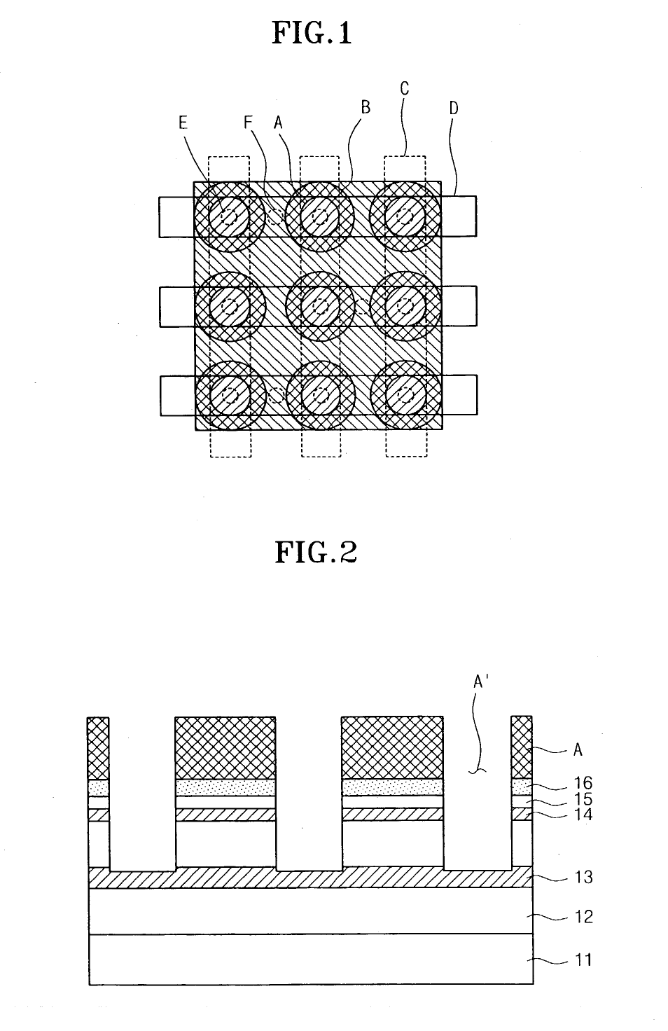

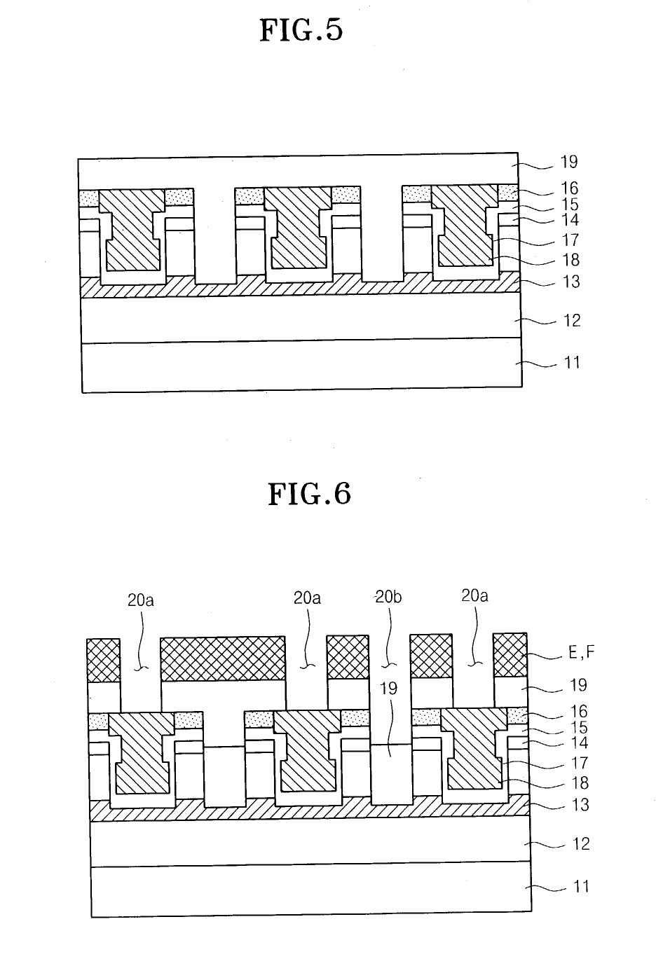

FIG. 1 shows an arrangement of masks used for fabricating a cylinder type transistor with a vertical silicon-on-insulator structure according to an embodiment of the present invention. FIGS. 2 to 7 are explanatory views in cross-section illustrating a cylinder type transistor with a vertical silicon-on-insulator structure and a fabrication method thereof according to an embodiment of the present invention.

Referring to FIG. 1, there is provided an arrangement of a transistor mask A, an isolation mask B, a word line mask C, a bit line mask D, a word line mask C, a bit line mask D, a word line contact mask E, and a bit line contact mask F. By using those types of masks A, B, C, D, E and F, the cylinder type transistor with the vertical-silicon-on insulator structure of the present invention is fabricated.

Referring to FIG. 2, a P-well zone 12 is formed on a silicon substrate 11 by using a P-well mask (not shown) and then an N+ drain 13 with a high density and an N+ source 14 with a high density are formed in sequence. Afterward, the P-well mask is removed. Here, the drain 13 and the source 14 are formed through an ion implantation process. Different depths can be obtained by setting the energies used for ion implantation differently.

Next, a masking oxide 15 and a masking nitride 16 are formed in sequence on an entire surface of the resultant structure and then a dry etching is performed using a transistor mask A. Here, the dry etching continues until the drain 13 is exposed. The masking nitride layer 16, the masking oxide 15, the source 14 and the P-well zone 12 are etched in sequence. The transistor mask A has a circular exposure area and a remaining shield area. Accordingly, a cylindrical trench A′ is formed by etching.

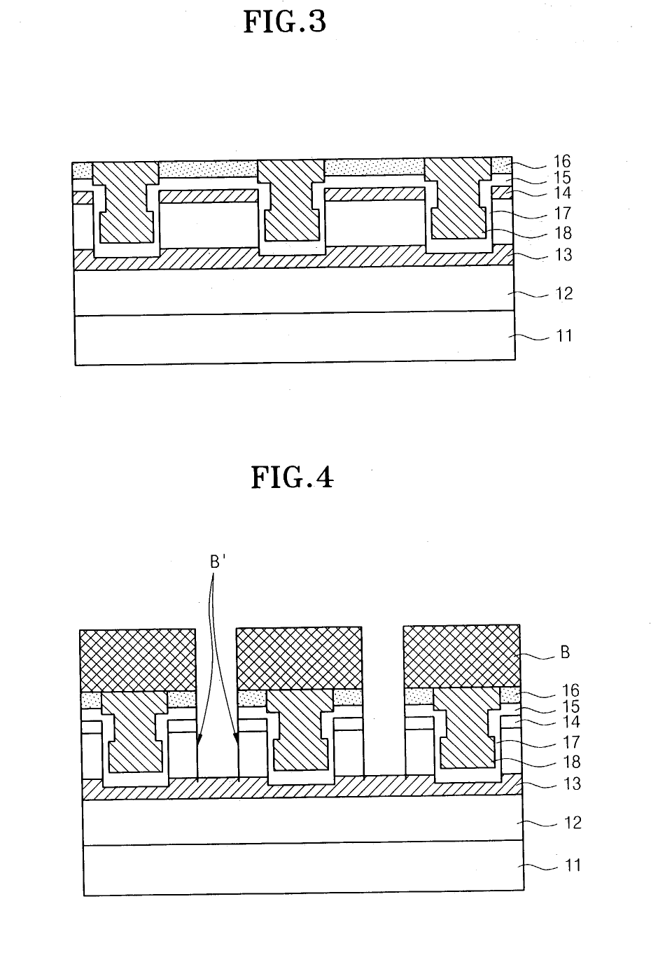

After removing the transistor mask A, a gate oxide layer 17 and a gate 18 are formed inside of the cylindrical trench A′ as shown in FIG. 3. The gate oxide layer 17 is formed by a thermal oxidation and the gate 18 is formed by a flattening process, such as chemical mechanical polishing (CMP) or blanket etch-back after the entire deposition of the gate material.

The gate oxide layer 17 grows up on the entire surfaces of the masking oxide layer 15, the source 15, the drain 13 and the P-well zone 12 exposed to the cylindrical trench A′ (FIG. 2). In particular, the growing-up of the gate oxide layer 17 doped with a high density in the source 14 and the drain 13 is five times or even ten times more than in other areas. For example, the thickness of the gate oxide layer 17 grown-up on the surface of the source 13 and the gate 18 will be more than 100 Å, if the thickness of the gate oxide layer 17 on the P-well zone 12 is about 20 Å. Accordingly, it is possible to reduce a parasitic capacitance between the source 14 or the drain 13 and the gate 18 and to reduce the current leakage from the source 14 or the drain 13 to the gate 18.

Next, as shown in FIG. 4, a dry etching is performed through use of the isolation mask B. Here, the dry etching continues until the drain 13 is exposed. The isolation mask B has a circular shield area and a remaining exposure area. Also, the circular shield area of the isolation mask B has a greater diameter than the circular exposure area of the transistor mask A. Accordingly, after the etching, the cylindrical bulk B′ is formed, the inside of which is filled with the gate oxide layer 17 and the gate 18 and outer wall of which is exposed.

Next, after removing the isolation mask B, an isolation oxide layer 19 is deposited on an entire surface of the resultant structure. Accordingly, a transistor channel is formed in the cylindrical silicon bulk B′ (FIG. 4) and the isolation oxide layer 19 fills spaces formed between outer walls of the silicon bulks B′. As such, the silicon-on-insulator (SOI) structure is obtained.

Afterward, the word line contact mask E and the bit line contact mask F are stacked to dry-etch the exposed isolation oxide 19 as shown in FIG. 6. As such, a word line contact hole 20a exposing an upper surface of the gate 18 and a bit line contact hole 20b exposing a side surface of the source 14 are formed.

Next, after removing the contact masks E and F, a word line contact plug 21a and a bit line contact plug 21b are formed in each of the contact holes. The contact plugs 21a and 21b are formed through the depositing of metallic material on an entire surface and flattening it. Then, by using the word line mask C and the bit line mask D shown in FIG. 1, a word line in contact with the word line contact plug 21a and a bit line in contact with the bit line contact plug 21b are formed.

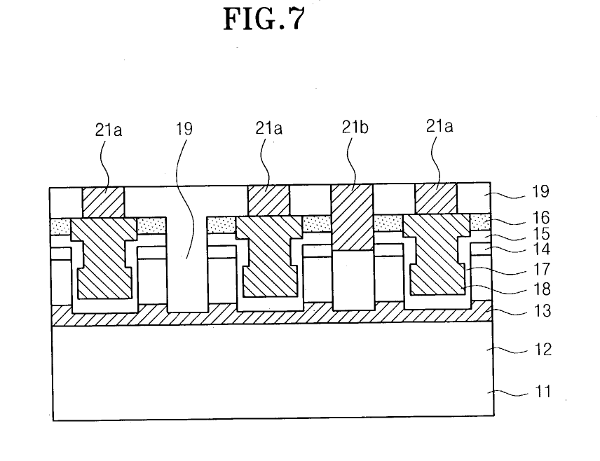

Alternately, the word line may directly contact with the gate without passing through the word line contact plug. In this case, the reference numeral 21a in FIG. 7 indicates a cross section of the word line, but not the word line contact plug. Otherwise, the bit line may directly contact with the source 14 without passing through the bit line contact plug. In this case the reference numeral 21b in FIG. 7 indicates a cross section of the bit line, but not the bit line contact plug.

The embodiment of the present invention described above is related to an NMOS transistor. However, the fabrication method of the present invention can be applied to the fabrication method of a memory device and a non-memory device as well as a PMOS transistor. Also, it can be applied to a silicon-on-insulator structure in which the outer wall of the silicon bulk corresponds to the transistor and the insulation layer fills the inner side.

As described above, the cylinder type transistor with the silicon-on-insulator structure and the fabrication method thereof according to the present invention make possible improved electrical characteristics and reliability and make it possible to obtain high integration.

More specifically, since the transistor channel is vertically formed, it is possible to increase a length of available channel without being affected by the extent of integration. Accordingly, it is possible to improve electric characteristics, such as that related to short channel effect, etc. Also, when applied to a memory cell, there will be little junction capacitance and the junction leakage current will be decreased because the thermal oxide layer grows up thickly in the region of the source and the drain, as it is doped with a high density. Additionally, as the junction leakage current will be decreased, it is possible to expect improvement in the refreshing characteristic of the device. Further, it is possible to obtain the high integration of the transistor owing to the vertical structure of the transistor.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A cylinder type transistor with a silicon-on-insulator structure, the transistor comprising:
a well zone of a first conductive type formed on a silicon substrate;
a drain of a second conductive type formed at a predetermined depth of the well zone;
a plurality of silicon bulks in the form of vertical cylinders located in the well zone above the drain;
a source of the second conductive type formed on each silicon bulk away from the drain in the vertical direction;
a gate filling the inside of each silicon bulk with a gate oxide layer interposed in each silicon bulk;
an isolation oxide layer formed on an entire surface of a resultant structure to expose a portion of the gate, the source and the drain; and
contact plugs electrically connected to the gate, the source and the drain, respectively, as exposed through the isolation oxide layer;
wherein a transistor channel is formed in each silicon bulk and the isolation oxide layer fills spaces formed between the outer walls of the silicon bulks.

2. A cylinder type transistor as claimed in claim 1, further comprising a masking oxide layer and a masking nitride layer formed on each silicon bulk.

3. A cylinder type transistor as claimed in claim 1 or 2, wherein the thickness of the gate oxide layer formed on the surface of the source and the drain is greater than that formed on the surface of the well zone.

4. A method for fabricating a cylinder type transistor, the method comprising steps of:
forming a well zone of a first conductive type on a silicon substrate;
forming a drain of a second conductive type at a predetermined depth of the well zone and forming a source above the well zone away from the drain in a vertical direction;
forming a cylindrical trench by etching the source and the well zone in sequence to expose the drain, using a transistor mask with a circular exposure area;
forming a gate oxide layer on an inner surface of the trench and forming a gate inside the trench;
forming a cylindrical silicon bulk, the inside of which is filled with the gate oxide layer and the gate and the outer wall of which is exposed, by etching the source and the well zone in sequence to expose the drain using an isolation mask, the diameter of a circular shield area of the isolation mask being greater than that of the circular exposure area of the transistor mask;
depositing an isolation oxide layer on an entire surface of a resultant to expose a portion of the gate, the source and the drain; and
forming contact plugs electrically connected to the drain, the source and the drain, respectively, exposed through the isolation oxide layer.

5. A method for fabricating a cylindrical transistor as claimed in claim 4, further comprising a step of forming a masking oxide layer and a masking nitride layer in sequence, after the step of forming the drain and the source.

6. A method for fabricating a cylindrical transistor as claimed in claim 4 or 5, wherein the step of forming the gate oxide layer is achieved by a thermal oxidization.
